(19) United States
(12) Patent Application Publication
(10) Pub. No.: US 2012/0111614 A1
(43) Pub. Date: May 10, 2012

(54) Integrated composite structure and electrical circuit utilizing carbon fiber as structural materials and as electric conductor

(76) Inventor: James J. Free, Elkhart, IN (US)

(21) Appl. No.: 12/927,392

(22) Filed: Nov. 10, 2010

(51) Int. Cl. H05K 1/09; B82Y 30/00

(52) U.S. Cl. 174/257; 977/735; 977/750; 977/752; 977/932

(57) ABSTRACT

A multifunctional paradigm is disclosed of “Strength Power to Weight”. Carbon tow is measured in individual fiber count per cross section. In terms of electrical conductivity, the individual fiber count total is analogous to a cross sectional wire gauge for corresponding metal (i.e. gold, copper, aluminum, silver, etc.). Tow segments are constructed/assembled/situated as being part of an electric circuit as well as being part of a laminated composite structure. For the electrical circuit, necessary electrical components are fixed to the carbon tow conductor using any of “soldering” (adhesive), “welding” (cohesion), or held in contact with mechanical force. The circuit is wetted out, allowed to cure (either before or along with the rest of the background laminate), and ultimately becomes a heterogeneous extremely light solid that conducts electrical power and provides additional structure to the composite as well.

### STATEMENT REGARDING FEDERALLY FUNDED RESEARCH AND DEVELOPMENT

NOT APPLICABLE

### FIELD

This invention relates to the use of carbon fibers as a structural material in a composite structure and also as a conductor of electrical power in an electrical circuit as well

### BACKGROUND OF THE INVENTION

Carbon fibers have long been in use as a structural composite material. The use of carbon fibers is constantly finding its way into new applications in aerospace, defense, sport and automotive as well as many other lightweight applications.

Automobile and airframe bodies have long been associated with the use of a conductive metal being used as a “ground” or even as a “Faraday Cage”. Bodies of components such as coils have also served as either a ground or some kind of conductor or carrier of charge (i.e. the preservation of a field). For many years automotive, and automotive special equipment components have included conductor cables (i.e. “house wire”) laminated into the panels and the like. Not to be left out would be the application of grounding out components ferromagnetically (i.e. including ferromagnetic grounding of automotive steel panels with each other to prevent static electric sparking and thus resistance to combustion in the close proximity of fuels). Aerospace frames have often had a Faraday Cage worked into the structure for grounding, and even EMI suppression and/or lightning suppression. The challenge for vehicles that depend on being strong and light is:

1. metal as a rule is heavier than high end composite for same inherent strength.

2. Structures utilizing a theme of framing with add-ons like wire harnesses, hook-ups, plug-ins, mounting brackets, hangers are heavier than solid state integrated structures.

Using a common aerospace paradigm of strength to weight ratio, the strength to weight of a properly constructed carbon composite laminate can exceed that of 6061 Aluminum or 4130 Chrome-moly steel by a factor of ten. Some high modulus versions of carbon fiber can go as high as a strength to weight twenty times greater than those metals.

Carbon has been associated with electrical conductivity since the beginning of the harnessing of electricity itself. It is still a main factor in electric components including dry cell batteries and motor brushes to name some.

Applications involving sophisticated aerostructures utilize electricity and strong lightweight materials. Aerostructures could further benefit from using the structure itself to conduct electricity

### SUMMARY OF THE INVENTION

Power can be associated with electricity transfer and Strength to Weight has long been associated with aerostructures and light structures. The results of research conducted by the inventor include a new paradigm of “Strength Power to Weight”.

Carbon tow is measured in cross sectional fiber total in analogy to appropriate metallic electrical conductive material (including gold, copper, silver, aluminum, brass, iron, and so on . . . ).

It is fixed at the terminal, connector or electrical contact or the like in three ways:

1. cohesive where carbon itself is included or involved in making an electrical contact,

2. adhesive where carbon is fixed by a conductive means that is non-carbon

3. where fibers are forced against a lead or terminal by mechanical means

After an electric or electronic assembly is wet out, it is placed into a laminate or coordinated into a unified structural, electronic package and allowed to cure. The assembly can be substantially started in cure earlier than being laid in; with the contacts substantially solid, there would be more mechanical strength to withstand the rest of the laminating process (including bagging, pressure forming, compression molding and so on). The circuit assembly can be laid in as wet at the rest of the laminate so that both would dry concurrently. While performing the laying in process for the latter fashion, the result must be that after the rigors of the rest of the lamination, the conductors and electrical functions must remain after the laminate is cured.

Laminating, preparation, “wet out”, pre cure handling modes include:
1 “wet” pre cured thermoset plastic resin
2. heat cured thermoresin before heating
3. ‘prepreg’ preimpregnated thermoset cold and curing at room temperature,
4. ‘prepreg’ that is to be heat cured,
5. pre heat-welded thermoplastic resin
6. pre fired ceramic processed material,
7. pre cured pre set (i.e. “still dry”) masonry
8. combinations of the above

For adhesive, a conductive epoxy commonly known in the art of electronics can impregnate the terminals or contacts and once the rest of the laminate is cured, the composite object becomes a solid state inter-conductive electrical circuit.

Nanostructures have been proven by the inventor to work in a cohesive process. They are impregnated with appropriate resin under appropriate treatment, laminated or processed in with the rest of the composite and allowed to cure.

Mechanical contacts can include spring force, spring force on secondary conductors (like alligator clip for example) bolt or screw or threaded tightening-clamp around or into a terminal, and so on.

Occasionally fibers break in a yarn or tow. In certain materials, SiC in a fired matrix for example, there is cross conductivity from fiber to fiber in the laminate. In other words, strands of fibers substantially going along with each other in the same general direction can pick up conductivity in a direction substantially perpendicular to the direction of the fibers and also the direction of the conductivity in the individual strands or filaments. In a standard epoxy carbon matrix, this is most often not the case; there is little or no conductivity in the “cross direction” from fibers. In other applications, carbon fiber in a thermoset matrix (Polyester or Epoxy, for example) there is little if any cross-fiber-directional conductivity in a bundle. In a long length of tow (per area of cross section), once an individual fiber is broken, the conductivity for those individual strands of fiber is lost.

Applications that could cause these breaks in a long conductive, non-cross-conductive matrix bundle include occasional breaks in processing or handling, laminating, breaks happening before a set or cure. Breaks that could occur after the cure, set or the like include heat, stress, non-homogenous material expansion. Destructive environments exposure could subject the long conductive fiber to a uniform breaking condition from the length of the source to the terminal at the sink.

Points along the conductive structural bundle can include conductive contacts including adhesive, cohesive, mechanical or combinations. For non cross fiber conductivity after cure, these contacts would reestablish all the fibers together conductively and minimize loss of fiber breakage for permanent solids and establish a minimum “remaining fiber conductive bundle” for a destructive environment, albeit the latter would be a moving factor per time throughout the use lifecycle of the product.

### OBJECT OF THE INVENTION

It is therefore an object of this invention to provide for an electrical circuit that also serves as structure where electrical power can be transmitted through a composite structure; use of fibers as electrical cabling, carbon composite fibers would have dual use as structure in the composite.

It is another object to allow for use as electrical contacts the inclusion of cohesion, adhesion, mechanical actuation processes or combinations of those.

Further, it is an object of the invention to provide for an economic manufacturing process of laminating/bagging/wet out means combined with modularity and integration in lieu of metal working, metal fabrication, bracket making and installation, wire harnesses, electrical plugs and the like.

It is another object to provide for processing options in wet out that include placing in pre-cured or modularly partial pre cured circuits into a wet laminate or layer, ranging to placing in tacked together wet circuits into the contemporarily wet background layers and letting them set concurrently.

It is a further object of this invention to provide for a composite structure that includes conductivity along long bundles of carbon fiber that when individual fiber breaks occur in the long bundle, various points along the way can have electrical conductivity reestablished by electrical contacts.

Moving now, to the drawings,

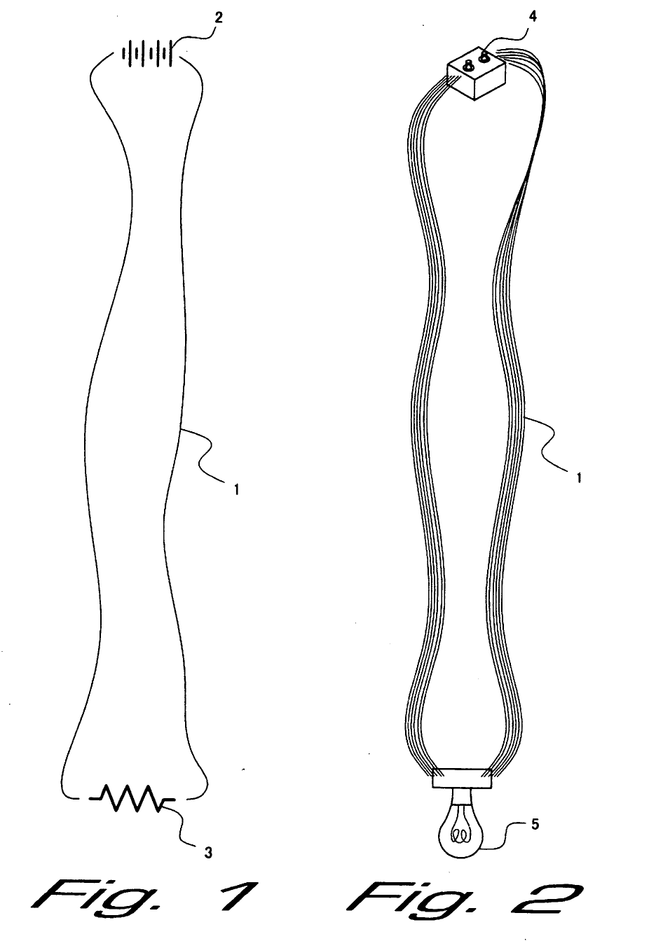

FIG. 1 shows a general schematic of a resistor with a DC power supply

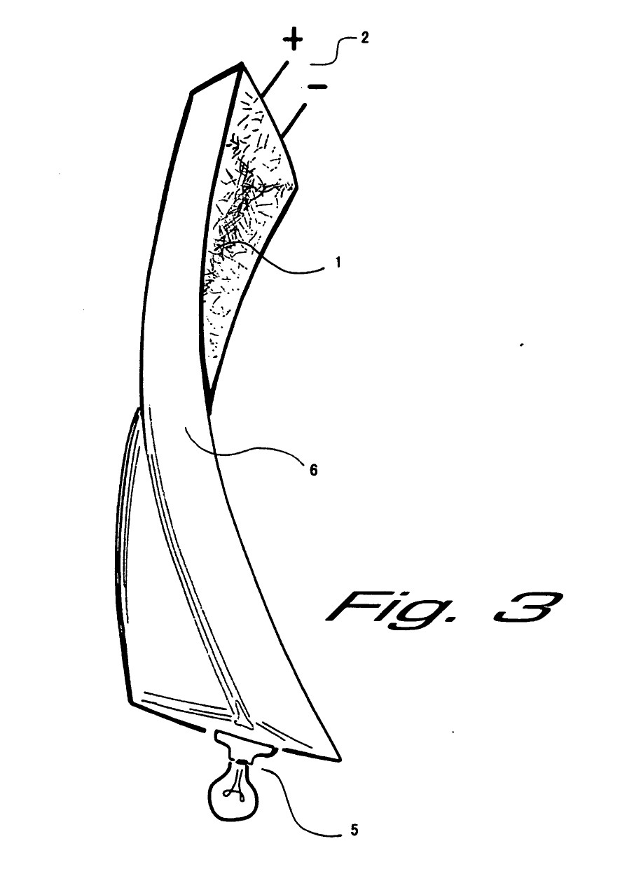

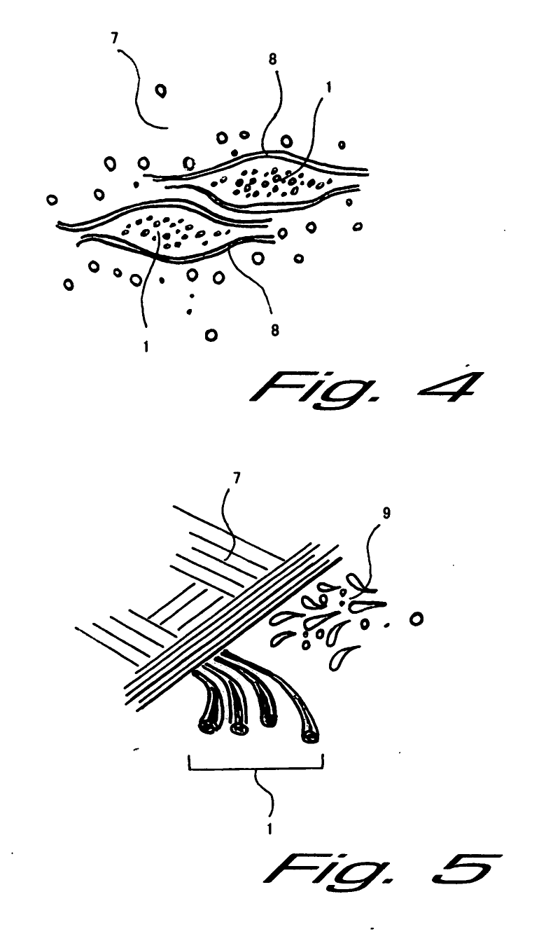

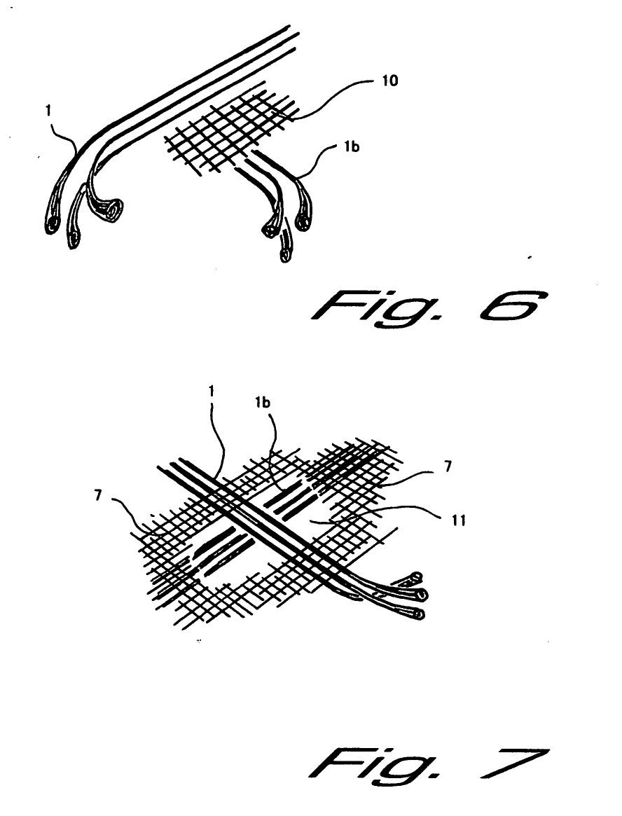

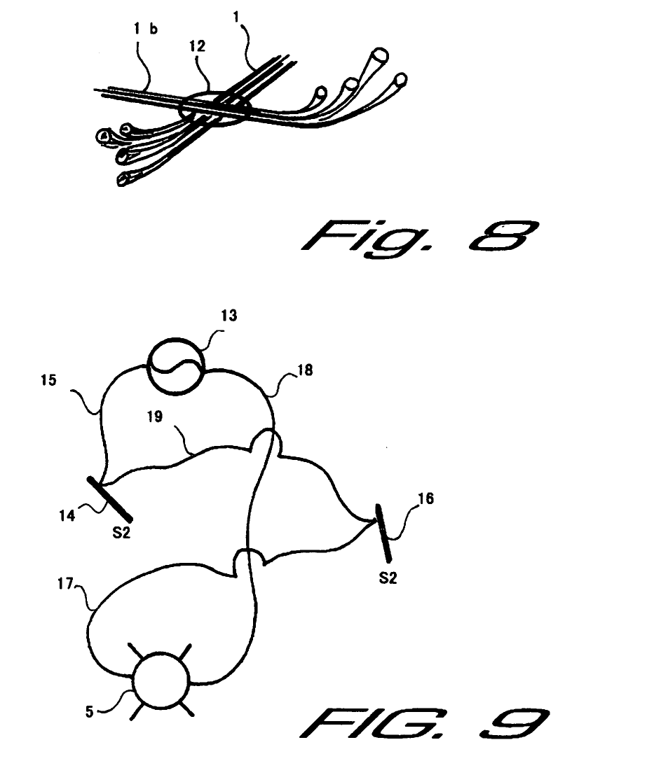

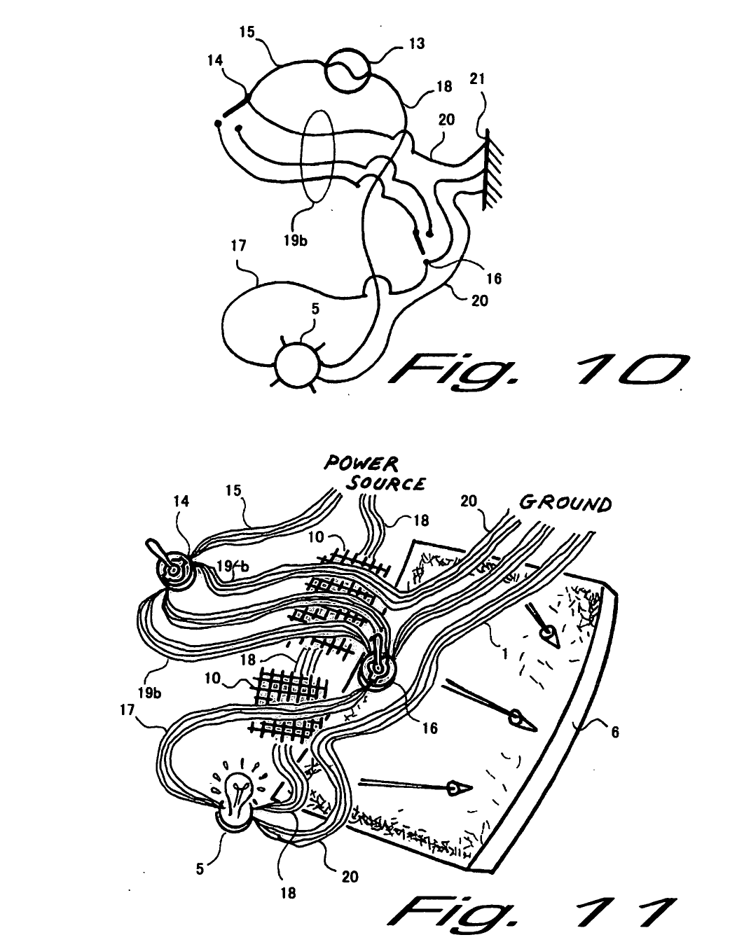

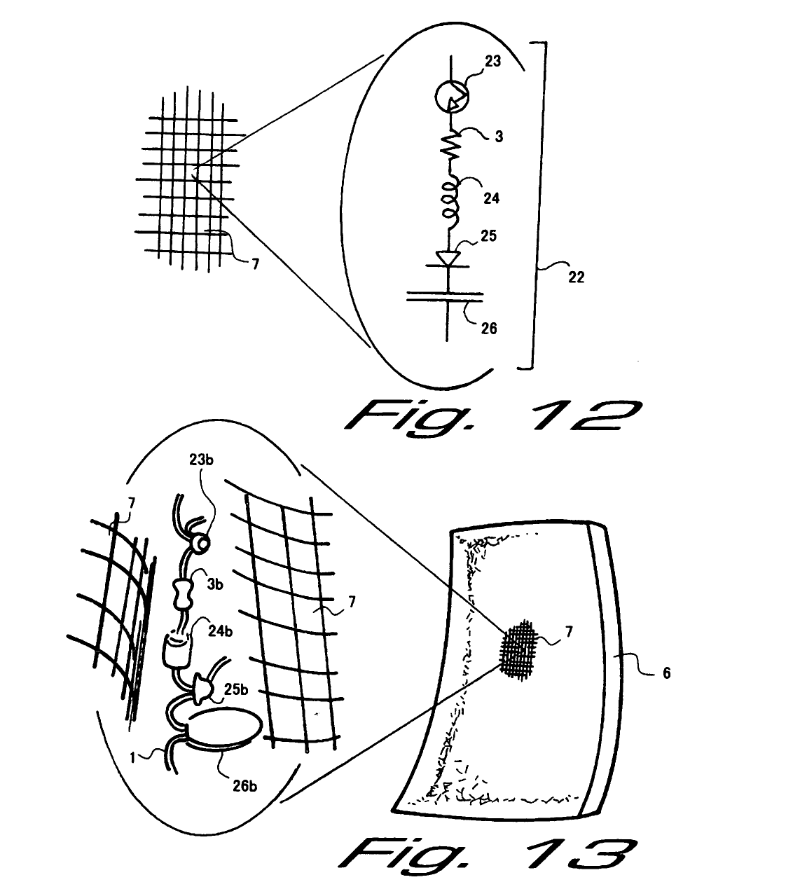

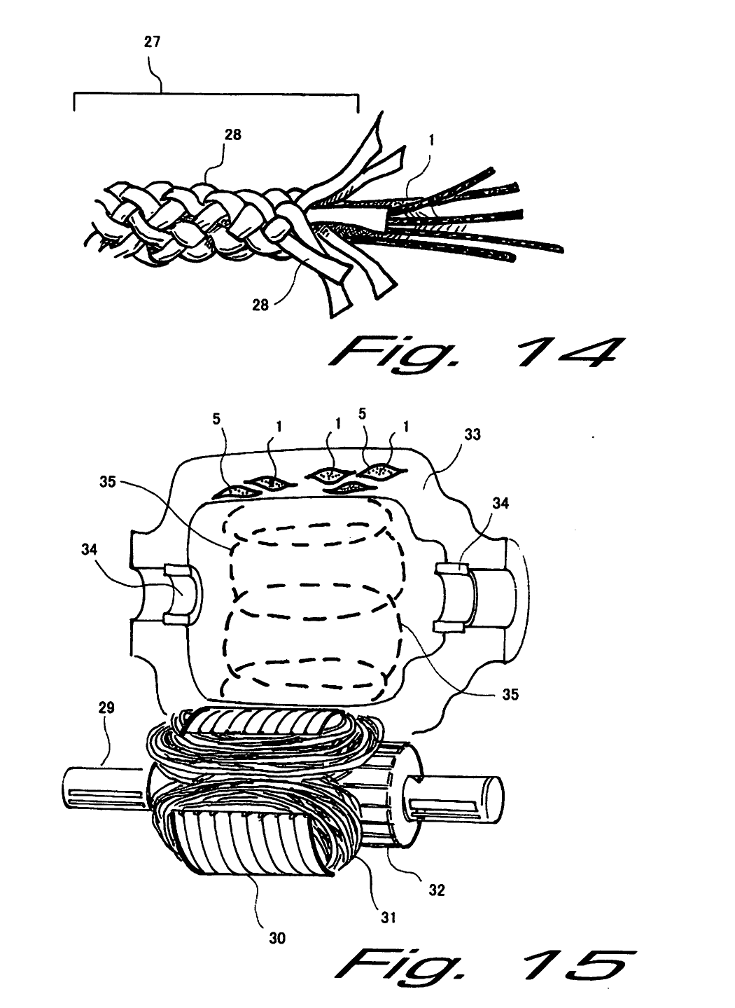

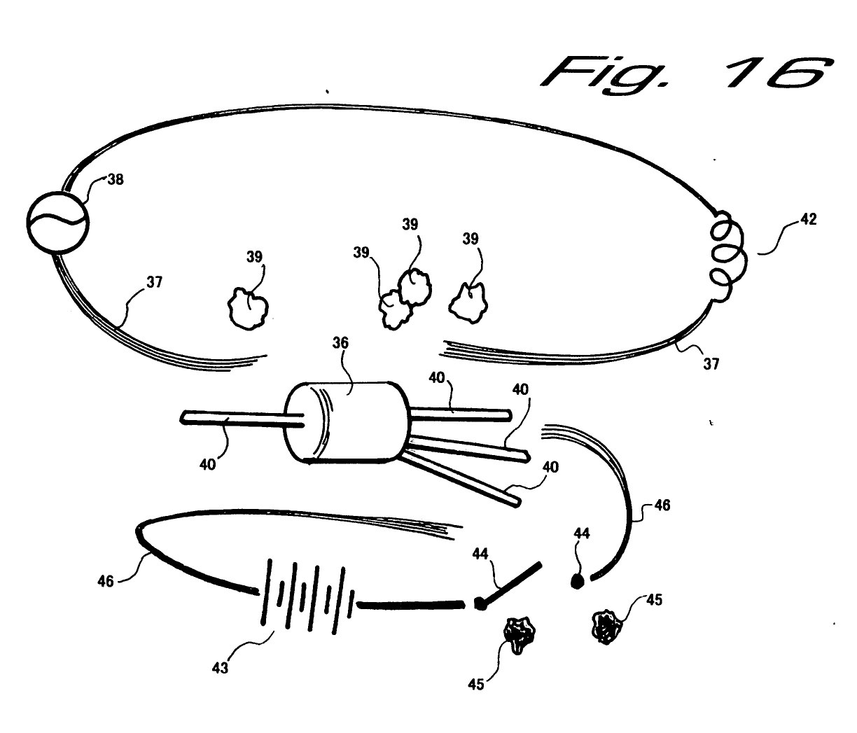

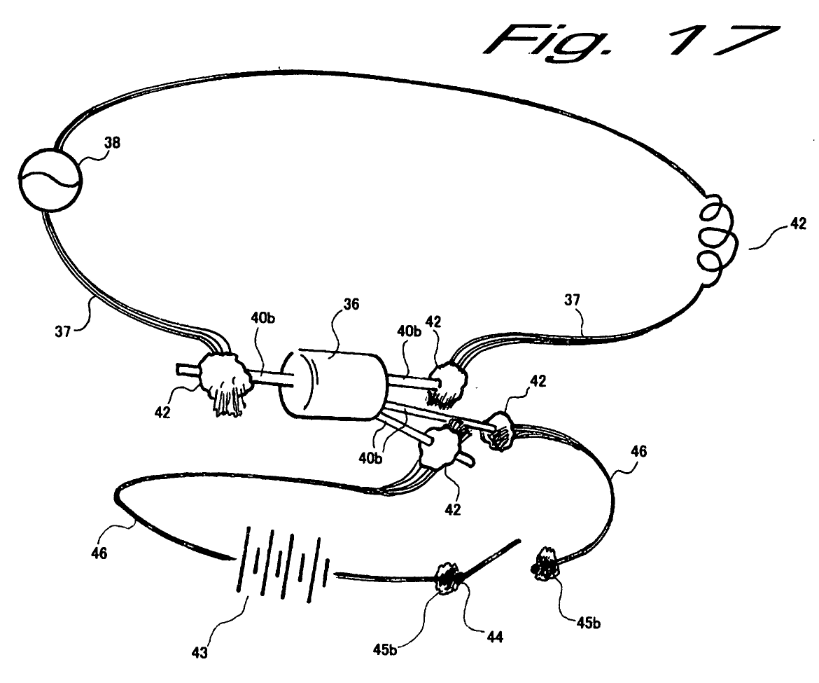

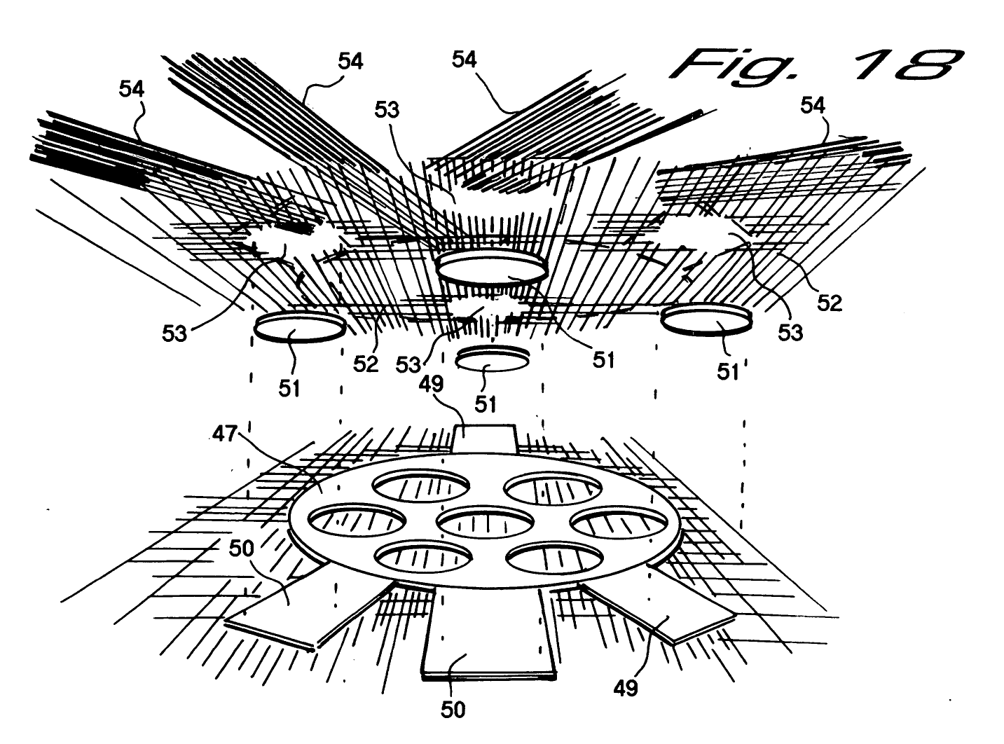

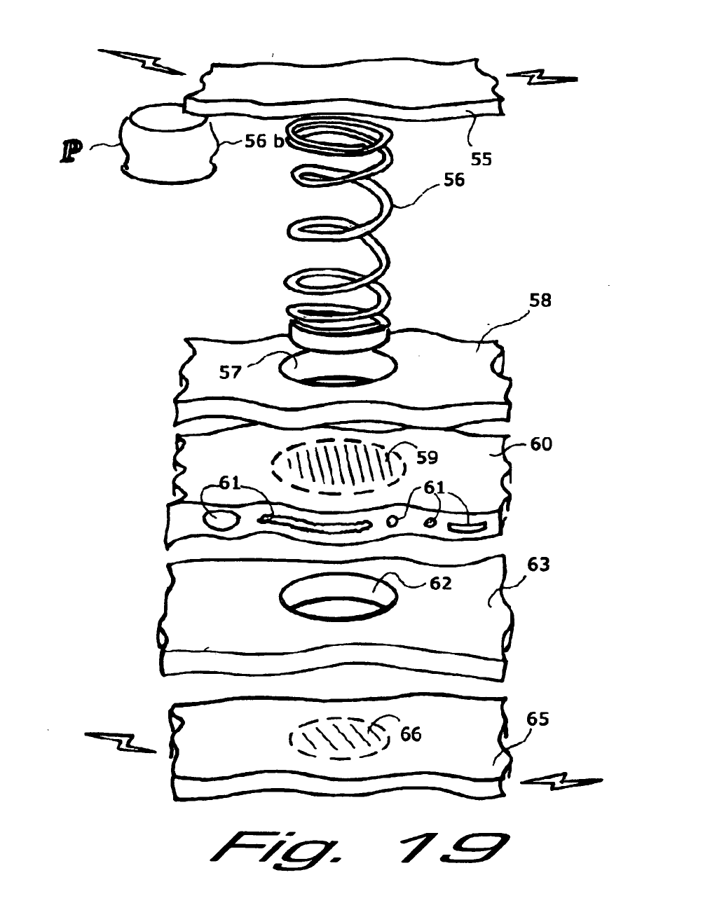

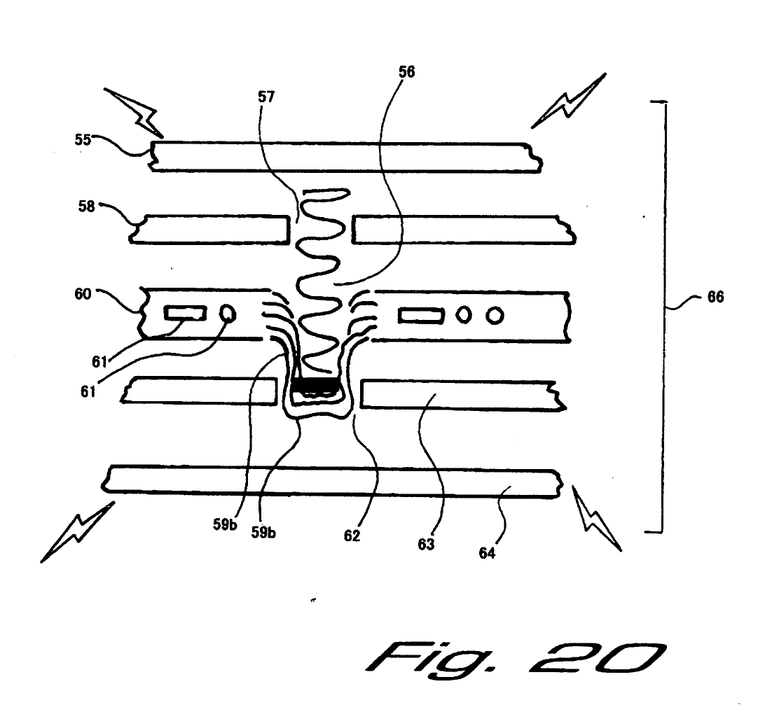

FIG. 2 shows a battery, a light fixture, and carbon fibers as the cable

FIG. 3 shows a laminate panel like structure with positive and negative terminals at one end and the light fixture at the other.

FIG. 4 includes a cross section of a laminate including background laminate, insulator, and carbon as conductor.

FIG. 5 shows the process of wetting out including background layer, matrix or resin, and carbon conducting/structural material

FIG. 6 shows the use of layering and carbon conducting yarns operating in different layers

FIG. 7 shows conducting yarns or bundles in different insulating layers with a break in the layering of the background laminate so that conductors can be allowed to have contact through the break.

FIG. 8 indicates a “soldered” or “welded” electric contact between two crossing bundles of yarn or conductive carbon fibers.

FIG. 9 shows a schematic with an AC power supply, a light fixture and a 3-way switch.

FIG. 10 includes greater detail of the AC power source and the 3-way including each of the runners involved with the 3-way and more detail of the switch.

FIG. 11 shows the actual circuit as would be placed into the laminate including the lead to AC power source, insulating separating layers of composite, panel, switches.

FIG. 12 shows a circuit detail that is much smaller relative to the panel that has the potential of being a microcircuit or nanocircuit while being in schematic form.

FIG. 13 shows the circuit as actual components as they are worked into a laminate and dropped into a panel.

FIG. 14 shows a carbon fiber bundle and a braid of insulating composite wrapped around it, with both bundle and braid serving as structure.

FIG. 15 shows a rotor and stator made of composite including carbon fiber yarn bundling as the conductor in the wrappings.

FIG. 16 shows a relay involving AC power source, DC power source, the use of conductively adhering, and the use of conductively cohering of electrical contacts in exploded view before assembly

FIG. 17 shows the relay after assembly

FIG. 18 includes relay components that are flat and tape-like.

FIG. 19 shows the exploded view of portions of a laminate that include a mechanical force involved as an electrical contact.

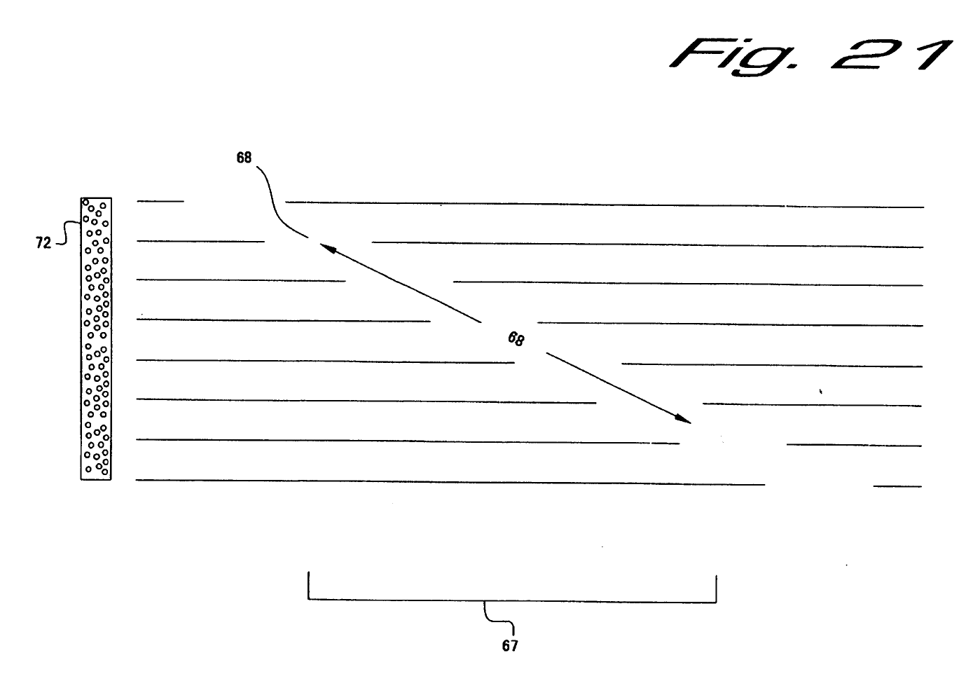

FIG. 20 shows that segment that involves mechanical force after lamination or assembly as a sandwich.

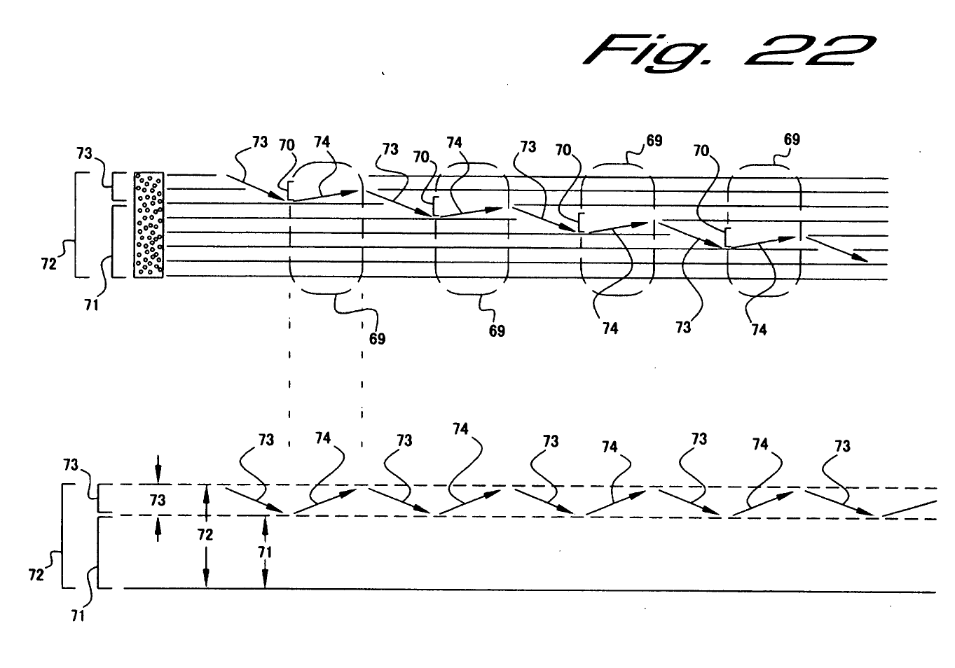

FIG. 21 shows a long segment of a bundle of conducting carbon fibers with symbolic break in individual fibers eventually creating an electrically conductive break throughout the section.

FIG. 22 shows the same bundle that includes diagrams of electrically conductive contacts and projected diagram of how conductivity is regained by means of those contacts.

### A DESCRIPTION OF A PREFERRED EMBODIMENT

Under no circumstances do the embodiments disclosed here represent the only form that this invention can take.

In [FIG. 1] electric power is conducted through a conductor 1 from a DC source 2 that powers resistor 3 as shown in a schematic diagram of a circuit. Power from the DC power source is shown as a battery 4 in [FIG. 2] as well as a pictorial representation showing carbon fibers 1, and resistor as a light bulb 5. This assembly is placed into and contributes to the structure of laminated composite panel 6 in [FIG 3].

In [FIG 4] a section view shows individual carbon fibers as electrically conductive material 1 being insulated from other conductors and background laminate 7 by means of insulating material 8.

[FIG. 5] shows the application of insulating material of which can be either resin, filler/resin combination or the like 9. This combination insulates carbon conductor 1 to prevent short circuits or drainage of electric power. All is encased by background laminate 7 where the fibers of which can also contribute to the insulating effect. In the event that conductors cross one another as shown by 1 and 1-b in [FIG. 6], insulating laminating fibrous or gauze-like materials 10 can help space the two conductors apart to avoid a short circuit while still contributing to the structure. Multiple carbon fiber conductive groups can be conductively joined as shown in 1, and 1-b in [FIG. 7], thus allowing circuits to be built with carbon fiber serving both as electrically conductive and structural material. Multiple layered laminating systems can be assembled similar to multi layered circuits as represented by conductive carbon fiber groups 1 and 1b which are joined through layers of insulating background lamination 7 by means of openings in background laminate 11. Layers can be further joined as an electrical conductive contact by physically connecting them as a contact 12 either adhesively (solder) or cohesively (weld) as shown in [FIG. 8].

### Alternative Embodiments #1

In [FIG. 9], a schematic of a two way switch includes alternating current (AC) power source 13, first two way switch 14, power to that switch 15 second two way switch 16, adjoining conductor 17, light fixture 5, returning line 18, and leg with runners 19. Closer detail is represented by wiring diagram in [FIG. 10] showing that cable with runner 19-b including the necessary runner cabling, is also accompanied by ground wires 20. Those wires from first switch 14 to second switch 16, single wires 15 and 17 connect runner cable 19-b to power source 13 and light fixture 5. System is grounded 21 by ground connections 20 to first switch 14, second switch 16, and light fixture 5. This system switches on the light fixture from either locations of positions of first switch 14 or second switch 16. In [FIG. 11], conductors shown as actual carbon fiber 19-b as well as 17 are laid across return conductor 18 and protected from that conductor by means of insulating laminated nonconductive fiber 10. Other conductors and ground wires are shown in position represented by carbon fiber conductor as they correspond to the diagram of [FIG. 10] with switches 14 and 16 as they are to be placed into and laminated in with laminated panel 6 with all carbon conductors not only conducting electricity, but contributing to the strength of laminated panel 6.

### Alternative Embodiment #2

Complex circuits 22 similar to microprocessors and integrated circuits are represented in [FIG. 12] by a tiny fragment of an extremely complex schematic diagram. A transistor 23 is connected to a resistor 3 which is connected to an inductor 24 followed by connection with a diode 25 and finally a capacitor 26. Those actual components are shown in assembly (in [FIG. 13]) with background laminate 7 and including a transistor 23-b connected to a resistor 3-b connected to an inductor 24-b followed by a diode 25-b and finally a capacitor 26-b all connected using carbon fibers 1 as a conductor as well as a structural material contributing to the strength of the background laminate 7 of composite laminated panel 6 that they are placed into.

In [FIG. 14], a “braid” 27 of fiber that has insulation qualities 28 as well as structural qualities such as S-glass (but could be weaker-strength E-glass or other type fiber just as easily) wraps conductive carbon fiber 1 such that after both are wet out and allowed to cure, they become structural and conductive with included insulation to prevent short circuit, power drain and the like. Also, they allow for easy and modular construction including impregnation/wet out.

In [FIG. 15] a motor, generator, or like coil device includes rotor 29 which supports ferrous plates 30 and carbon fiber wrappings 31 connected through conducting brush plates 32. Rotor 29 is held in place within stator 33, which is composite, and journals rotor 29 within bearings 34. Stator 33 shown in section includes stator wrappings 35 that make up structure as well as conductivity. Stator wrappings 35 consist of individual groups of conductive fibers 1 that are numbered enough to conduct the appropriate electricity the same as the corresponding cross sectional gauge of metal (i.e. gold, copper, silver, aluminum, etc.). The fibers 1 are insulated by being surrounded by electrically insulating composite resin and/or fiber 5.

Preferred Operation

In [FIG. 16] a relay 36 that switches an AC line 37 coming from power source 38, and with said line 37 being carbon fiber, is “soldered” or conductively adhered 39 to leads 40. Load in the circuit includes running device 42 as well as resistance from conductor 37. Relay 36 is switched on and off by DC loop including power source 43 with electrical conductor that is carbon fiber 46. Switch 44 is “welded” or conductively cohered in with carbon nanostructures 45 to carbon fiber conductor 46 and allowed to cure along with adhered soldering 39 of leads/contacts 40 to carbon conductor 37. Also cohering 45 of switch 44 to carbon conductor 46 is allowed to cure.

In [FIG. 17], the system involving relay 36 has soldered leads 40-b in the AC line either soldered and substantially cured or soldered in a manner that it can be laid in substantially wet with the rest of the wet laminate (not shown) where both cure together. In either case of circuit laminated in as cured or laminated in while contacts are still wet, the contacts will be still conductive when overall laminate is dry/cured. Also if assembled with both wet, the circuit adhesions will still be conductive. Also, the adhesions will not be contaminated with the rest of the non conductive resin (especially if laminated in while wet). Additionally, the contacts 40-b, and conductor 37 will be electrically insulated adequately to the degree that a short circuit will not occur.

In the same manner, switch 44 is cohered 45-b to carbon tow of DC input 46, and either laid in wet with the rest of the wet laminate (not shown) or laid in after being substantially cured. Conductive cohesion 45-b is maintained by not contaminating said cohesion with the non conductive rest of the laminate (not shown). In either case of circuit laminated in as cured or laminated in while contacts are still wet, the contacts will be still conductive when overall laminate is dry/cured, and the circuit cohesions will still be conductive. Also, the contacts 45-b and conductor 46 will be electrically insulated to an adequate degree that a short circuit will not occur.

In [FIG. 18], an electrical component with similarity to the relay of [FIGS. 16 and 17] is flat or tape like 47 and lays against a preimpregnated or prepreg sheet 48 (similar to background laminate 7 in [FIGS. 4,5,6,7,11,13]).

Said Prepreg sheet 48 could be in a wide range of techniques that start as chilled to cure at room temperatures (Standard Temperature and Pressure; STP) to starting at room temperature to be oven-cured). Tape like leads or contacts for load, line 49, and switching 50 accept prepreg adhesive or cohesive pads 51 to lay on them while being vacuum bagged pressed, pressure formed or the like. Upper prepreg sheet 52 has holes 53 to match leads of load and line 49 and switching 50, pads 51, such that when assembly is easily laid out, carbon tapes 54 are matched with the holes. When assembly cures under press or vacuum bag, assembly becomes a circuit that takes advantage of tapes 54 diagonally reinforcing and conducting component with other components as well.

Mechanical contact methodology is shown in [FIG. 19]. Electrically powered surface 55 could be a bolted on cover but more realistically, a laminated conductive layer of composite. Spring loaded conductive electrical contact 56 has separating force that wants to push apart. Contact could just as easily be a gas filled bladder 56-b that provides increased expansion force in an atmospheric differential. Spring contact 56 or bladder 56-b or combination of the two project through hole 57 in layer of laminate that is non conductive (i.e. because of insulating/filler resin, or using glass as fibers) 58. While spring contact or bladder 56, 56-b (exerting gas pressure “P”) or combination exert force through hole 57, said hole 57 aligns with a flexible, intentionally “dry” or non laminated spot 59 of carbon fiber electrical circuit layer 60 that includes leads, other components, or the like 61 wired into said electric circuit and laminate. Hole 62 in another insulating layer 63 projects to a spot 64 in second electrical conducting layer 65. When assembled, processed or laminated as shown in [FIG. 20], the system is a closed sandwich 66. Spring contact 56 or the like conducts electricity and forces against the loose carbon fibers 59-b of dry unlaminated spot 59 (in [FIG. 19]). Said dry spot 59 and 59-b is part of carbon layer 60 that contains circuit-components 61. Due to spring contact 56, said dry spot 59-b is forced against second conductive layer 64 through hole 62 in second insulating layer 63. Said spring contact 56 (or like mechanical means) is journaled or held in place within hole 57 in non conductive layer 58.

### Alternative Embodiment #3

An alternative embodiment is disclosed wherein there is an application of a long conductive bundle of carbon fibers 67 (in [FIG. 21]). With certain processing or handling situations, or destructive environments (such as fatigue cycling, particle fragments or the like) there could be a large or complete eventual break 68 in the aggregate conductivity of a conductive bundle 67. In [FIG. 22], there are one or more connective contacts, terminals or the like (i.e. as cohesive or adhesive) 69. Electric power/conductivity takes place form source (not shown) towards each contact 69 such that loss from broken material 70 is kept to a minimum since at each contact 69, conductivity is reestablished throughout the bundle of remaining conductors 71 by inter-conductivity provided from contact 69.

Therefore, when a chart of overall conductivity is projected in [FIG. 22], to the diagram including contacts, loss in conductivity from broken or breaking fibers 73 is corrected on a contact to contact basis 74. The loss due to breaking fiber is minimized to local repeating losses 73 as opposed to theoretically most or all fibers breaking and having little or no contact or conductivity 68 (in [FIG. 20]).

Broken fibers 70 occurring before contacts 69 are reestablished in conductivity with all the other remaining conductors of a cross section 71. Therefore (in [FIG. 22]), there is minimum loss because there remains a minimum conductive fiber availability 71.

What is claimed is:

1. A hybrid purpose electricity conducting and light structural composite laminate comprising of:
an electric circuit that includes some or all electrical power cables/wiring made of carbon fiber,
a composite laminate that provides structure,
wherein said electrical power transmission means/conductivity/analogy-of-wiring can serve the purpose of conducting the electricity as well as providing for the structure in said laminate,
wherein due to said carbon fiber providing dual purpose of conductivity and structure, that said overall structure can be lighter in weight,

2. The system of claim 1 wherein said electrical circuit is assembled substantially beforehand, and/or where cure or setting process is began substantially before placing into or among rest of laminate,
wherein while pre processed circuit may be more hardened than the background laminate as it is placed in, that it successfully integrates with the rest of the surrounding composite,
wherein by being placed into laminate after cure or setting process has begun, the circuit assembly is more mechanically stable and can better absorb laminating type processes and retain its conducting and functioning integrity during processes of manufacture.

3. The system of claim 1 wherein elements of the circuit are substantially assembled in the laminate at essentially the same time while all are substantially wet at the same time and all are allowed to cure substantially concurrently,
composite joining electrically conducting means is assembled pre-impregnated with a pre-impregnated remaining composite and both are substantially allowed to cure concurrently,
wherein said electrically conducting means having been installed while wet is not contaminated by non conducting remainder of laminate.

4. The system of claim 1 that uses adhesive process as a conducting means for electrical contacts

5. The system of claim 1 that uses cohesive process as a conducting means for electrical contacts

6. The system of claim 1 that uses outside mechanical means to actuate, cause force to or create pressure against electrical contacts.

7. The system of claim 4 wherein said adhesive is conductive thermoset resin.

8. The system of claim 5 wherein said cohesive process involves carbon nanostructures.

9. The system of claim 8 wherein said Carbon nanostructures include buckminsterfullerene molecules or “Bucky Balls”.

10. The system of claim 8 wherein said Carbon Nanostructures include any or all of nanotubes, single wall, double wall, multiwall, and combinations of the above.

11. The system of claim 8 wherein there is a mixture of buckyballs balls and nanotubes.

12. The system of claim 7 that uses silver based conductive thermoset resin.

13. The system of claim 7 that uses non silver based conductive thermoset resin

14. The system of claim 1 that includes the use of occasional soldering (adhesive), welding (cohesive) or mechanical force against fibers, or any combination of the above along a path of an electrically powered bundle of carbon fibers,
wherein conductivity is reestablished in spite of individual fiber breakage loss, across the whole cross section of the conductive bundle,
wherein if there is occasional severing of part of the bundle, that those fibers that have lost power due to being severed can regain power through the electrical contact therefore redistributing power throughout cross section of the bundle,
wherein continuous breaks of individual fibers along the length of a long conductive bundle will result in minimum loss of voltage.

15. A dual purpose multifunctional smart structure composite laminate,
that includes electrical circuit as part of its composition,
wherein said electrical circuit is made up of carbon fiber,
wherein said carbon fiber contributes to some of the structure as well as the conductivity in cabling/wiring, electric power transmission,
wherein the circuit element is laid in during the lamination
wherein lamination can be all substantially at the same time or in various steps taking a long period of time,
wherein laid while wet can include process techniques including wet STP layup catalyzed concurrently for both circuit and background layers,
multiple pass vacuum bagging, pre fired ceramic/carbon carbon matrix, thermoset resin, thermoplastic resin, pre-cured masonry, pre-heat prepared thermoresin, pre-sonic welded thermoresin or combinations,
wherein means for electrical contact includes adhesive processes, cohesive process, application of mechanical force or combinations of those.

16. The system of claim 12 that uses silver in conductive epoxy resin.

17. The system of claim 8 wherein said nanostructures can include combinations of different species of small structures including microstructures, and nanostructures.

18. The system of claim 1 wherein layup/wet out processes include techniques that range throughout the pressure and temperature spectrum.

19. The system of claim 18 wherein said temperature and pressure spectrum includes Standard Temperature and Pressure; STP,
wherein wet out and catalization techniques range throughout pressure and thermal differentiation while coming up with substantially the same result,
wherein thermal differentiation can range from cold starting prepregs that cure at room temperature to room temperature prepregs that cure at elevated temperatures, and wherein the middle of that range can include catalyzing and curing substantially at room temperature STP,
wherein atmospheric differentiation can range from zero pressure at a vacuum to STP at atmosphere to vac-bagging at substantially 2 atm to pressure forming and compression molding to substantially more pressure than that.
